(19) United States
(12) Patent Application Publication
(10) Pub. No.: US 2012/0135605 A1
(43) Pub. Date: May 31, 2012

(54) METHOD FOR FORMING SIDE-CONTACT REGION IN SEMICONDUCTOR DEVICE

(76) Inventor: Won-Kyu KIM, Gyeonggi-do (KR)

(21) Appl. No.: 13/231,259

(22) Filed: Sep. 13, 2011

(30) Foreign Application Priority Data
Nov. 26, 2010 (KR) 10-2010-0118748

(51) Int. Cl. H01L 21/3105

(52) U.S. Cl. 438/696; 257/E21.241

(57) ABSTRACT

A method for fabricating a semiconductor device includes forming a first trench by etching a substrate, forming a liner layer on a surface of the first trench, forming a sacrificial spacer pattern covering one sidewall of the first trench over the liner layer, forming a second trench by etching the substrate under the first trench using the sacrificial spacer pattern and the liner layer as etch barriers, forming a protection layer on a surface of the second trench, and forming a side contact region by selectively removing the protection layer formed on an upper portion of one sidewall of the second trench.

### CROSS-REFERENCE TO RELATED APPLICATIONS

The present application claims priority of Korean Patent Application No. 10-2010-0118748, filed on Nov. 26, 2010, which is incorporated herein by reference in its entirety.

### BACKGROUND

1. Field

Exemplary embodiments of the present invention relate to a method for fabricating a semiconductor device, and more particularly, to a method for forming side-contact regions of a semiconductor device.

2. Description of the Related Art

A cell of a vertical transistor structure has a three-dimensional (3D) structure that includes an active region, which is formed of a body and a pillar disposed over the body, a buried bit lines (BBL), and a vertical gate (VG).

The bodies of neighboring active regions are isolated from each other by trenches, and a buried bit line is formed in each trench. The buried bit line is electrically connected with any one sidewall of the body of the active region. A vertical gate disposed over the buried bit line is formed on the sidewalls of the pillar of the active region, and a source and a drain are formed in the active region. A channel is formed by the vertical gate between the source and the drain in a vertical direction.

A One-Side-Contact (OSC) process is performed to form a buried bit line driving one cell. The OSC process may also be referred to as a Single-Side-Contact (SSC) process. Hereafter, the OSC process is simply referred to as a side contact process. The side contact process is a process of exposing a portion of a sidewall of one active region while insulating a sidewall of another active region, wherein the sidewalls are opposite.

FIG. 1 is a cross-sectional view illustrating a side contact formed according to a prior art.

Referring to FIG. 1, a trench 102 is formed by etching a substrate 100 using a hard mask layer 101 as an etch barrier. An active region 103 is defined by the trench 102 to have two sidewalls. After an insulation layer 104 covering both sidewalls of the active region 103 is formed, a side contact region 105 that exposes a portion of any one sidewall of the active region 103 is formed by etching a portion of the insulation layer 104.

Referring to FIG. 1, the side contact region 105 exposes a portion of any one sidewall of the active region 103. A polysilicon layer may be used as a mask layer for exposing a portion of any one sidewall of the active region 103. For example, a polysilicon layer is formed and then ions are implanted into a portion of the polysilicon layer by performing a tilt ion implantation process. Subsequently, the region of the polysilicon layer implanted with ions or a region not implanted with ions is selectively removed and then the remaining region is used as a mask layer.

However, since memory devices to which high integration design rule is applied have active regions of high aspect ratio, the process for forming the side contact regions 105 is complicated. In particular, with forming a polysilicon layer and then performing the tilt ion implantation process alone, it is difficult to expose the desired depth and location of sidewall of the active region 103.

### SUMMARY

An embodiment of the present invention is directed to a semiconductor device fabrication process that may easily form a side contact in a desired depth and location.

In accordance with an embodiment of the present invention, a method for fabricating a semiconductor device includes: forming a first trench by etching a substrate; forming a liner layer on a surface of the first trench; forming a sacrificial spacer pattern covering one sidewall of the first trench over the liner layer; forming a second trench by etching the substrate under the first trench using the sacrificial spacer pattern and the liner layer as etch barriers; forming a protection layer on a surface of the second trench; and forming a side contact region by selectively removing the protection layer formed on an upper portion of one sidewall of the second trench.

### BRIEF DESCRIPTION OF THE DRAWINGS

FIG. 1 is a cross-sectional view illustrating a side contact formed according to a prior art.

FIGS. 2A to 2M are cross-sectional views illustrating a method for forming side contacts of a semiconductor device in accordance with an embodiment of the present invention.

FIG. 3 is a cross-sectional view illustrating a method for forming buried bit lines in accordance with an embodiment of the present invention.

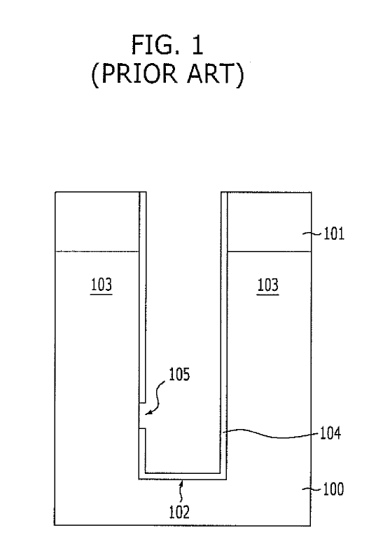

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

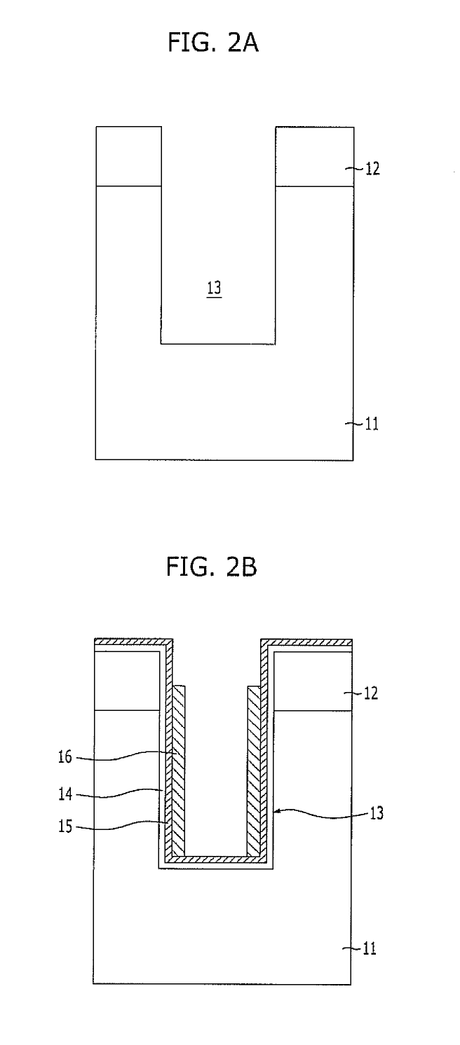

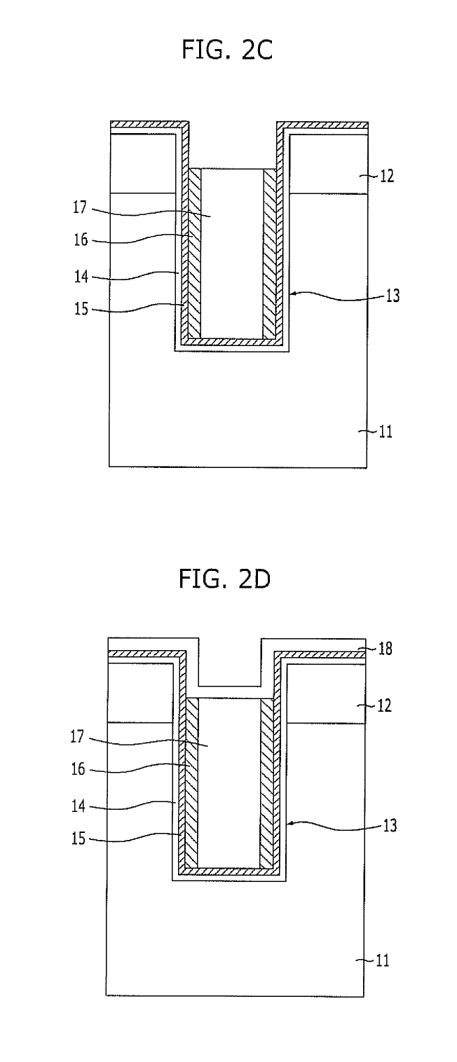

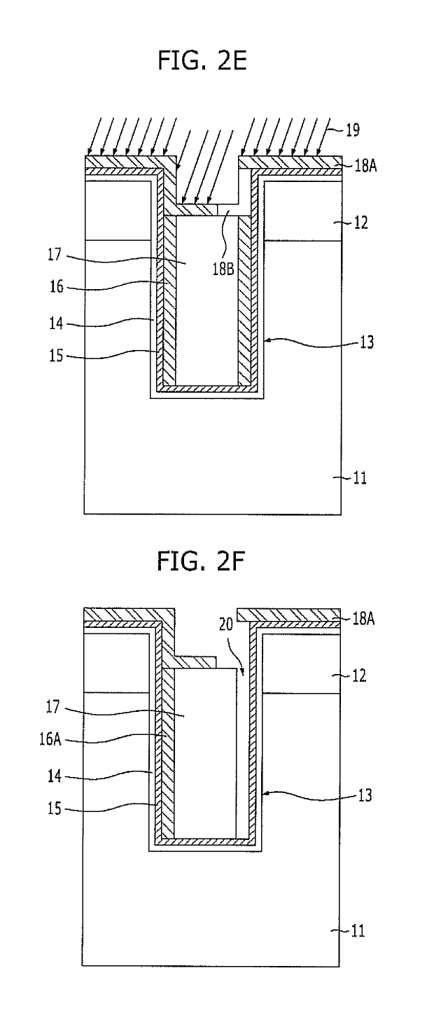

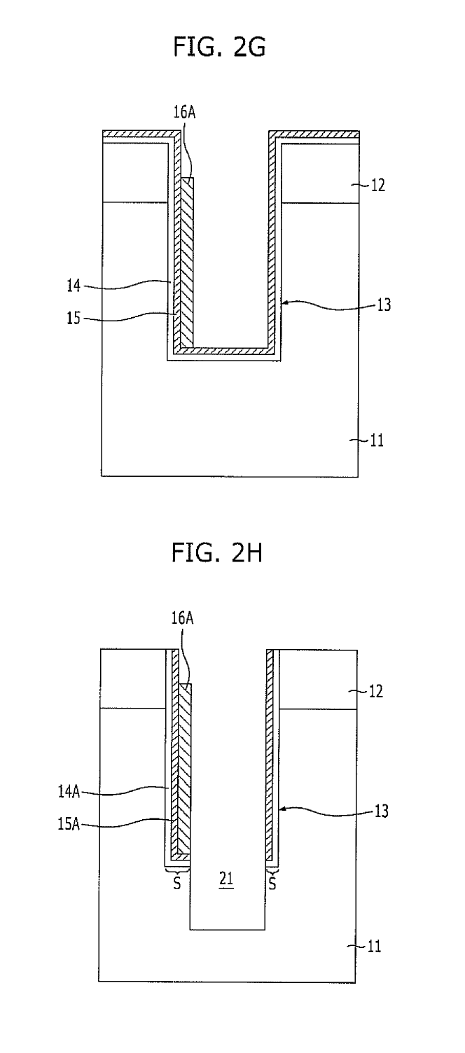

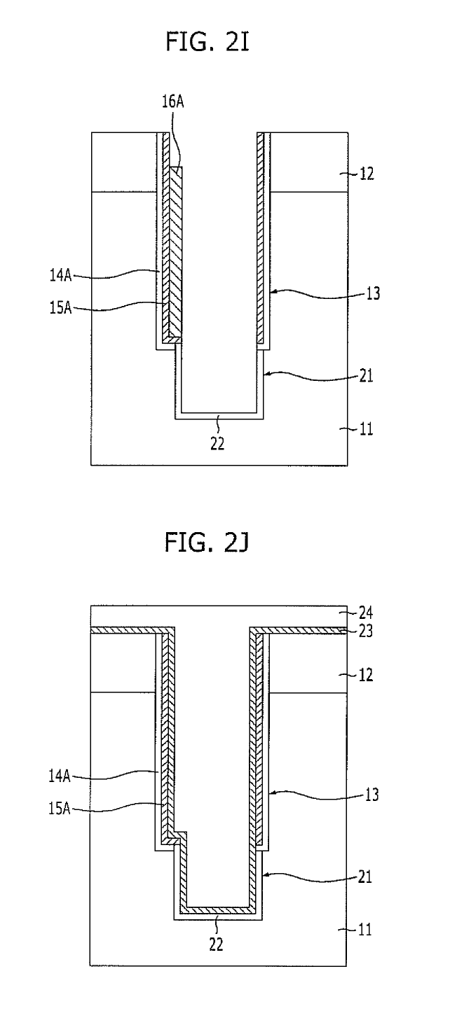

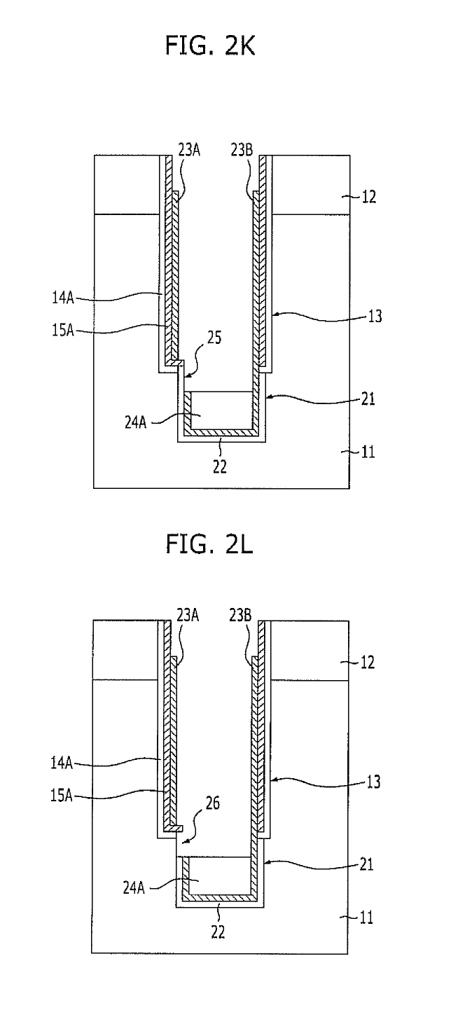

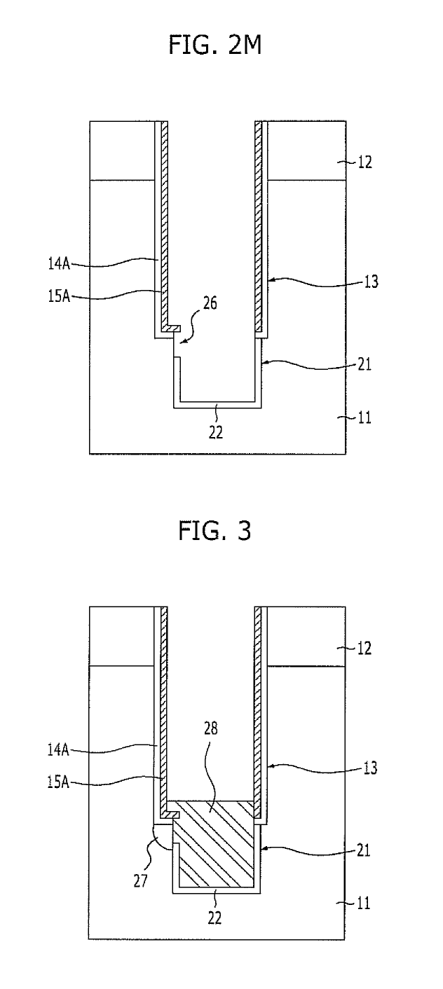

FIGS. 2A to 2M are cross-sectional views illustrating a method for forming side contacts of a semiconductor device in accordance with an embodiment of the present invention.

Referring to FIG. 2A, a hard mask pattern 12 is formed over a substrate 11 such as a semiconductor substrate. The substrate 11 comprises a silicon substrate. The hard mask pattern 12 may comprise an oxide layer, a nitride layer, or a stacked layer where a nitride layer and an oxide layer are stacked. For example, the stacked layer may have a structure where a hard mask nitride layer and a hard mask oxide layer are sequentially stacked.

Subsequently, the hard mask pattern 12 is formed using a photosensitive layer (not shown) which is patterned in a line-space type.

A first trench etch process is performed using the hard mask pattern 12 as an etch barrier. In other words, a first trench 13 is formed in the substrate 11 by using the hard mask pattern 12 as an etch barrier and etching the substrate 11 by a predetermined depth.

Since the first trench 13 is formed by using the hard mask pattern 12 as well, they are patterned in the line-space type. Accordingly, the first trench 13 has a shape of line.

The first trench etch process may be an anisotropic etch process. When the substrate 11 is a silicon substrate, the anisotropic etch process may be a plasma dry etch process using chlorine (Cl₂) or hydrogen bromide (HBr) gas alone or a mixed gas thereof.

Referring to FIG. 2B, a first liner layer 14 is formed over the substrate structure including the first trench 13. The first liner layer 14 includes an oxide layer, e.g., a silicon oxide layer. Therefore, the first liner layer 14 is referred to as a liner oxide layer.

A second liner layer 15 is formed over the first liner layer 14. The second liner layer 15 includes a nitride layer, e.g., a silicon nitride layer. Therefore, the second liner layer 15 is referred to as a liner nitride layer.

Subsequently, sacrificial spacers 16 covering the sidewalls of the second liner layer 15 are formed. The sacrificial spacers 16 are formed by depositing a metal nitride layer and then performing a spacer etch process. The sacrificial spacers 16 include a titanium nitride (TiN) layer. The top of the sacrificial spacers 16 may be lower than the top of the hard mask pattern 12. For example, when the spacer etch process is an etch-back process, the etch amount and etch time are controlled in such a manner that the top of the sacrificial spacers 16 is lower than the top of the hard mask pattern 12.

Referring to FIG. 2C, a gap-fill layer 17 gap-filling the first trench 13 is formed over the substrate structure including the sacrificial spacers 16. The gap-fill layer 17 includes an oxide layer. Particularly, a Spin-On Dielectric (SOD) layer may be used to gap-fill the first trench 13 without forming voids.

Subsequently, the gap-fill layer 17 is planarized until the surface of the second liner layer 15 is exposed. Here, the gap-fill layer 17 may be planarized through a Chemical Mechanical Polishing (CMP) process.

Subsequently, the gap-fill layer 17 is recessed to a predetermined depth. Here, the recessed depth of the gap-fill layer 17 is adjusted to expose the upper surface of the sacrificial spacers 16.

Referring to FIG. 2D, a third liner layer 18 is formed over the substrate structure including the recessed gap-fill layer 17. The third liner layer 18 includes a polysilicon layer. The third liner layer 18 may be an undoped polysilicon layer.

Referring to FIG. 2E, a tilt ion implantation 19 is performed. The tilt ion implantation 19 is a process for implanting the ions of a dopant at a predetermined angle. A portion of the third liner layer 18 is implanted with the dopant (see 18A).

The tilt ion implantation 19 is performed at a predetermined angle, which ranges from approximately 5° to approximately 30°. The hard mask pattern 12 shadows a portion of the third liner layer from ion beam (see 18B). Therefore, a portion of the third liner layer 18 is doped but the other portion remains undoped. For example, the dopant ion-implanted is a P-type dopant, e.g., boron, and a dopant source used for ion-implanting boron is boron difluoride (BF₂). As a result, a portion of the third liner layer 18 remains undoped and this is the portion adjacent to one side of the hard mask pattern 12.

As a result of the tilt ion implantation 19 of the dopant, the portion of the third liner layer 18 disposed on the upper surface of the hard mask pattern 12 and adjacent to the other side of the hard mask In pattern 12 become a doped third liner layer 18A that is doped with the dopant. The third liner layer 18 that is not doped with the dopant becomes an undoped third liner layer 18B.

Referring to FIG. 2F, the undoped third liner layer 18B is removed. Here, the polysilicon layer used as the third liner layer is etched at different etch speeds/rates depending on whether it is doped with the dopant or not. In particular, the undoped polysilicon layer that is not doped with the dopant may be etched fast. Therefore, the undoped polysilicon is selectively removed by using a chemical having a high selectivity that may wet-etch the undoped polysilicon. The undoped third liner layer 18B is removed through a wet etch process or a wet cleaning process.

After the undoped third liner layer 18B is removed as described above, the doped third liner layer 18A remains. Also, the upper portion of one sacrificial spacer 16 is exposed.

Subsequently, the sacrificial spacer 16 whose upper portion is exposed is removed. As a result, a gap 20 is formed between the gap-fill layer 17 and the second liner layer 15.

Referring to FIG. 2G, the doped third liner layer 18A is stripped and the gap-fill layer 17 is removed. The gap-fill layer 17 is removed through a dip-out process using a hydrofluoric acid (HF) or buffered oxide etchant (BOE) solution.

When the gap-fill layer 17 is removed, a sacrificial spacer 16A remains on one side of the trench 13 and the sidewall of the second liner layer 15 is exposed on the opposite side.

Referring to FIG. 2H, a second trench etch process is performed. Here, the second trench etch process is performed to form a trench in alignment to the sacrificial spacer 16A. During the second trench etch process, the first liner layer 14 and the second liner layer 15 that are formed on the hard mask pattern 12 and the bottom of the first trench 13 is etched, and the substrate 11 under the first trench 13 is etched by a predetermined depth. Here, the remaining first liner layer 14 and second liner layer 15 are referred to as a first liner layer pattern 14A and a second liner layer pattern 15A.

A second trench 21 is formed as a result of the second trench etch process, and one sidewall of the second trench 21 is aligned to the sacrificial spacer 16A, while the other sidewall of the second trench 21 is aligned to the second liner layer pattern 15A. After all, the second trench 21 is formed under the first trench 13, and areas of the shoulders S of the second trench 21 under the first trench 13 are different from each other. The different areas of the shoulders are determined based on the width of the sacrificial spacer 16A. For example, in FIG. 2H, the area of the left shoulder is wider than the area of the right shoulder.

As described above, when the second trench 21 is formed, a double trench of the first trench 13 and the second trench 21 is formed in the substrate 11. The double trench has two sidewalls. Accordingly, active regions (not denoted by a reference numeral) that are isolated from each other by the double trench of the first trench 13 and the second trench 21 are formed in the substrate 11.

Referring to FIG. 2I, a protection layer 22 is formed on the surface of the second trench 21. The protection layer 22 includes an oxide layer, e.g., a silicon oxide layer. The protection layer 22 may be formed in the bottom and sidewalls of the second trench 21 through a wall oxidation process. The wall oxidation process includes a plasma oxidation process.

Referring to FIG. 2J, the sacrificial spacer 16A is removed.

Subsequently, a first sacrificial layer 23 is formed over the substrate structure including the protection layer 22. The first sacrificial layer 23 includes a titanium nitride (TiN) layer.

Subsequently, a second sacrificial layer 24 is formed over the substrate structure including the first sacrificial layer 23 to gap-fill the double trench. Here, the first sacrificial layer 23 and the second sacrificial layer 24 are removed after a subsequent process is performed. For example, the second sacrificial layer 24 includes a Spin-On Carbon (SOC) layer. The SOC is a carbon prepared through a spin coating process.

Referring to FIG. 2K, an etch-back process is performed on the second sacrificial layer 24. The etched second sacrificial layer 24 is referred to as a second sacrificial layer pattern 24A. The second sacrificial layer 24 is etched to form the second sacrificial layer pattern 24A filling a portion of the second trench 21.

Subsequently, a spacer etch process is performed onto the first sacrificial layer 23. When the first sacrificial layer 23 is spacer-etched, a portion of the protection layer 22 formed in the upper sidewall of the second trench of the double trench is exposed (see reference numeral ‘25’). This is because first sacrificial layer patterns 23A and 23B remaining after the spacer etch process does not have a form of a continuing layer, but have a disconnection point. The disconnection point is located in the boundary between the first trench 13 and the second trench 21, which is the under the region where the sacrificial spacer 16A is removed. More specifically, in FIG. 2K, it is one upper sidewall of the second trench 21.

Referring to FIG. 2L, the exposed protection layer 22 is removed. As a result, a side contact region 26 that exposes a portion of one upper sidewall of the second trench 21 is formed. Since the protection layer 22 is an oxide layer, a wet etch method is used. For example, a hydrofluoric acid (HF) or buffered oxide etchant (BOE) solution is used to form the side contact region 26.

Referring to FIG. 2M, the second sacrificial layer pattern 24A and the first sacrificial layer patterns 23A and 238 are removed. Since the second sacrificial layer pattern 24A is of Spin-On Carbon, it is removed using oxygen plasma. The first sacrificial layer patterns 23A and 23B are removed through a sulfuric acid peroxide mixture (SPM) cleaning process.

As a result, the side contact region 26 that exposes a portion of one sidewall of the double trench coated with the first liner layer pattern 14A, the second liner layer pattern 15A, and the remaining protection layer 22 is formed.

FIG. 3 is a cross-sectional view illustrating a method for forming buried bit lines in accordance with an embodiment of the present invention.

Referring to FIG. 3, a junction region 27 is formed on one sidewall of the active region exposed by the side contact region 26. The junction region 27 may be formed through an ion implantation process and/or a plasma doping process. Also, the junction region 27 may be formed by performing a gap-filling process with a doped layer, e.g., a doped polysilicon layer, and then performing a thermal treatment. The dopant of the doped layer may include an N-type impurity, such as phosphorus (P). Therefore, the junction region 27 becomes an N-type junction.

Subsequently, a buried bit line 28 coupled with the junction region 27 is formed. The buried bit line 28 has an adequate height to fill the second trench 21. The buried bit line 28 is insulated from the substrate 11 by the protection layer 22, the first liner layer pattern 14A, and the second liner layer pattern 15A, except the portion coupled with the junction region 27. The buried bit line 28 is formed by thinly forming a titanium layer and a titanium nitride layer and then performing a gap-filling process with a tungsten layer. Subsequently, a planarization process and an etch-back process are performed so that the buried bit line 28 fills the second trench 21 at least. Here, the titanium layer and the titanium nitride layer are barrier metals. A silicide may be further formed on the surface of the junction region 27 after the barrier metal is formed. The silicide serves as an ohmic contact between the junction region 27 and the buried bit line 28 and it decreases contact resistance.

As described above, since the buried bit line 28 is formed of a metal layer, it has a low resistance. Also, since one junction region 27 is coupled with one buried bit line 28, high integration of a semiconductor device may be fabricated.

According to an embodiment of the present invention, the depth and location of a side contact may be uniformly controlled by forming a double trench and a sacrificial spacer. Also, since the variation in the depth and location of a side contact is reduced, the process may be easily controlled and production yield may be increased.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a first trench by etching a substrate;
forming a liner layer on a surface of the first trench;
forming a sacrificial spacer pattern covering one sidewall of the first trench over the liner layer;
forming a second trench by etching the substrate under the first trench using the sacrificial spacer pattern and the liner layer as etch barriers;
forming a protection layer on a surface of the second trench; and
forming a side contact region by selectively removing the protection layer formed on an upper portion of one sidewall of the second trench.

2. The method of claim 1, wherein the forming of the side contact region comprises:
removing the sacrificial spacer pattern;
forming a sacrificial layer gap-filling the first trench and the second trench over a substrate structure from which the sacrificial spacer pattern is removed;
exposing the protection layer formed on the upper portion of the one sidewall of the second trench by selectively removing the sacrificial layer; and
removing the exposed protection layer.

3. The method of claim 2, wherein the forming of the sacrificial layer comprises:
forming a first sacrificial layer over a surface of the substrate structure; and
forming a second sacrificial layer gap-filling the first trench and the second trench over the first sacrificial layer.

4. The method of claim 3, wherein the exposing of the protection layer formed on the upper portion of the one sidewall of the second trench comprises:
etching the second sacrificial layer in the second trench partially; and
exposing the protection layer formed on the upper portion of the one sidewall of the second trench by performing a spacer etch process onto the first sacrificial layer.

5. The method of claim 3, wherein the first sacrificial layer comprises a titanium nitride layer, and the second sacrificial layer comprises a Spin-On Carbon (SOC) layer.

6. The method of claim 1, wherein the protection layer is formed through a wall oxidation process.

7. The method of claim 1, wherein the sacrificial spacer pattern comprise a titanium nitride layer.

8. The method of claim 1, wherein the liner layer is formed by stacking an oxide layer and a nitride layer.

9. The method of claim 1, wherein the forming of the sacrificial spacer pattern covering the one sidewall of the first trench comprises:
forming sacrificial spacers covering the one and the other sidewalls of the first trench over the liner layer;
forming a gap-fill layer which gap-fills the first trench over the sacrificial spacers;
recessing the gap-fill layer;
forming a mask layer over the recessed gap-fill layer, wherein the mask layer has a non-ion implantation region that ranges from an upper portion of the recessed gap-fill layer to an upper portion of the liner layer formed on the other sidewall of the first trench;
removing the non-ion implantation region; and
removing the sacrificial spacer exposed after the non-ion implantation region is removed.

10. The method of claim 9, wherein the non-ion implantation region of the mask layer is formed by performing a tilt ion implantation process on the mask layer.

11. The method of claim 10, wherein the mask layer comprises a polysilicon layer.

12. The method of claim 11, wherein the removing of the non-ion implantation region is performed by using a chemical having a high selectivity for wet-etching an undoped polysilicon.

13. The method of claim 10, wherein the tilt ion implantation process is performed at a set angle, which ranges from approximately 5° to approximately 30°.

14. The method of claim 10, wherein a dopant used for the tilt ion implantation process comprises boron.

15. The method of claim 10, wherein a dopant source used for the tilt ion implantation process comprises boron difluoride (BF₂).
